(19) United States
(12) Patent Application Publication
(10) Pub. No.: US 2011/0216487 A1
(43) Pub. Date: Sep. 8, 2011

(54) Electronic apparatus for vehicle

(75) Inventor: Naoki Sakai, Okazaki-city (JP)

(73) Assignee: DENSO CORPORATION, Kariya-city (JP)

(21) Appl. No.: 12/926,752

(22) Filed: Dec. 8, 2010

(30) Foreign Application Priority Data
Mar. 8, 2010 (JP) 2010-51096

(51) Int. Cl. H05K 5/00

(52) U.S. Cl. 361/679.01

(57) ABSTRACT

An electronic apparatus for a vehicle, which includes a partition wall that partitions between an engine room and a passenger compartment of the vehicle, includes an electronic device, a housing, and an annular rubber member. The electronic device is received in the housing. The housing is placed in the engine room and is fixed to the partition wall by a fixing member. The partition wall has a through-hole to oppose the housing, and the housing has an opening that communicates between an internal space of the housing and the passenger compartment. An annular rubber member is arranged to surround the through-hole of the partition wall and the opening of the housing, and the rubber member is clamped between the housing and the partition wall when the housing is fixed to the partition wall by the fixing member.

### CROSS REFERENCE TO RELATED APPLICATION

The present application is based on Japanese Patent Application No. 2010-51096 filed on Mar. 8, 2010, the disclosure of which is incorporated herein by reference.

### FIELD OF THE INVENTION

The present invention relates to an electronic apparatus for a vehicle.

### BACKGROUND OF THE INVENTION

As an in-vehicle waterproof device having an electronic component in an internal space thereof and configured to be installed to a position in a vehicle, on which water is poured, an electronic control unit arranged in an engine room of a vehicle is well-known, as described in JP-A-2007-141959 corresponding to US 2007/0109730. The electronic control unit includes a waterproof case equipped with a breathing filter for breathing internal and external air of the waterproof case.

Since a pressure difference between an internal pressure and an external pressure of the breathing filter can be suppressed by using the breathing filter, deformation due to expansion of the breathing filter can be suppressed. Moreover, a filter membrane configuring the breathing filter is made of water-shedding fibrous material. Thus, liquid such as water is restrained from passing through the breathing filter and gas can pass through the breathing filter.

In contrast, in a waterproof housing described in JP-A-6-216544 corresponding to EP 0606752 A1, a circular hole is formed in a main body of the waterproof housing arranged in an engine room. A connecting tube is inserted in the circular hole from, a flange portion side, and the connecting tube is connected to the main body. A connecting portion between the connecting tube and the main body is fixed by adhesive agent, and the connecting portion is air-tightly sealed. A hose is connected to one end of the connecting portion, and the other end of the connecting portion is placed in a passenger compartment.

According to such a configuration, even if an internal pressure of the waterproof housing is increased, expanded air can be made to flow into the passenger compartment through the connecting tube and the hose.

In the configuration described in JP-A-2007-141959, in order to secure a waterproof property and suppress an internal-external pressure difference, the breathing filter is needed. The breathing filter itself is expensive and fixing steps may be increased. Thus, if the breathing filter is used, manufacturing cost may be increased.

In contrast, in the configuration described in JP-A-6-216544, the waterproof property can be secured and the internal-external pressure difference can be suppressed without using the breathing filter.

However, as described above, since the configuration of JP-A-6-216544 is complicated due to the connection structure of the connecting tube to the main body of the waterproof housing and the air-tightly sealing with the adhesive agent, it is difficult to reduce the manufacturing cost.

### SUMMARY OF THE INVENTION

In view of the above-described problems, it is an object of the present invention to provide an electronic apparatus for a vehicle, which can secure a waterproof property without a breathing filter and can suppress an internal-external pressure difference.

According to one aspect of the present invention, an electronic apparatus for a vehicle, which includes a partition wall that partitions between an engine room and a passenger compartment of the vehicle, includes at least one electronic device, a housing, and an annular rubber member. The housing receives the at least one electronic device in an interior of the housing. The housing is adapted to be placed in the engine room of the vehicle and is adapted to be fixed to a mount area of the partition wall of the vehicle, which has a through-hole, with at least one fixing member. The through-hole extends through the partition wall at the mount area to oppose the housing upon fixation of the housing to the mount area of the partition wall with the at least one fixing member. The housing includes an opening, which communicates between the interior of the housing and the passenger compartment through the through-hole of the partition wall. The annular rubber member surrounds the opening of the housing and is adapted to be placed in an imaginary plane that is generally perpendicular to a penetrating direction of the through-hole of the partition wall to surround the through-hole of the partition wall and the opening of the housing. The rubber member is adapted to be clamped between the housing and the partition wall upon the fixation of the housing to the partition wall with the at least one fixing member.

In the above-described configuration, the rubber member is located in the opposing area in which the housing and the partition wall are opposed to each other. When the housing is fixed to the partition wall with the fixing member, the rubber member is elastically deformed, and thereby the rubber member is clamped between the housing and the partition wall. The rubber member clamped between the housing and the partition wall is in an elastic deformation state, and the rubber member air-tightly contacts the housing and the partition wall.

The rubber member is placed to surround the through-hole of the partition wall and the opening of the housing in the direction generally parallel to the imaginary plane. Thus, an internal space of the housing is communicated with the passenger compartment through the opening of the housing, the annular rubber member, and the through-hole of the partition wall.

Therefore, for example, if a pressure in the internal space is increased, expanded air in the internal space can be made to flow to a side of the passenger compartment. That is, an internal-external pressure difference can be suppressed without using a breathing filter.

Furthermore, as described above, the rubber member air-tightly contacts the housing and the partition wall, and the internal space of the housing is communicated with only an inner side of the passenger compartment. Therefore, although the housing is arranged at a side of the engine room, a waterproof property of the internal space can be secured.

Specifically, in the present invention, the housing is fastened and fixed to the partition wall by the use of the annular rubber member, so that the waterproof property can be secured without using the breathing filter and the internal-external pressure difference can be suppressed. Therefore, the above-described configuration is simplified compared with the configuration of related arts, and thereby, manufacturing cost can also be reduced.

Furthermore, since the housing is fixed to the partition wall, heat generated in the electronic device can be released to the partition wall, a heat-releasing property can be improved.

### BRIEF DESCRIPTION OF THE DRAWINGS

The above and other objects, features and advantages of the present invention will become more apparent from the following detailed description made with reference to the accompanying drawings. In the drawings:

FIG. 1 is a perspective view showing a structure of an electronic control unit according to a first embodiment of the present invention;

FIG. 2 is a cross-sectional view taken along the line II-II of FIG. 1;

FIG. 3 is a top view showing a fixation position of the electronic control unit to a vehicle; according to the first embodiment of the present invention;

FIG. 4 is a cross-sectional view showing a fixation structure, in which the electronic control unit is fixed to a partition wall, according to the first embodiment of the present invention;

FIG. 5 is a plan view showing a positional relation among an opening, a through-hole, and a rubber member, according to the first embodiment of the present invention;

FIG. 6 is a cross-sectional view showing a fixation structure of an electronic control unit, according to a second embodiment of the present invention;

FIG. 7 is a cross-sectional view showing a fixation structure of a first modified example of the second embodiment of the present invention;

FIG. 8 is a cross-sectional view showing a fixation structure of a second modified example of the second embodiment of the present invention;

FIG. 9 is a cross-sectional view showing a fixation structure of a third modified example of the second embodiment of the present invention; and

FIG. 10 is a cross-sectional view showing a fixation structure of an electronic control unit, according to a third embodiment of the present invention.

### DETAILED DESCRIPTION OF THE PREFERRED EMBODIMENTS

Hereinafter, embodiments of the present invention will be described with reference to drawings.

### First Embodiment

As an in-vehicle waterproof device, the present embodiment shows an example of an electronic control unit having a waterproof structure, which is used as an engine ECU (Electric Control Unit) for a vehicle.

In addition, in the embodiments of the present invention, as shown in FIG. 4 and the like, a thickness direction of a partition wall 53 is referred to as a thickness direction, and a direction perpendicular to the thickness direction is referred to as a vertical direction.

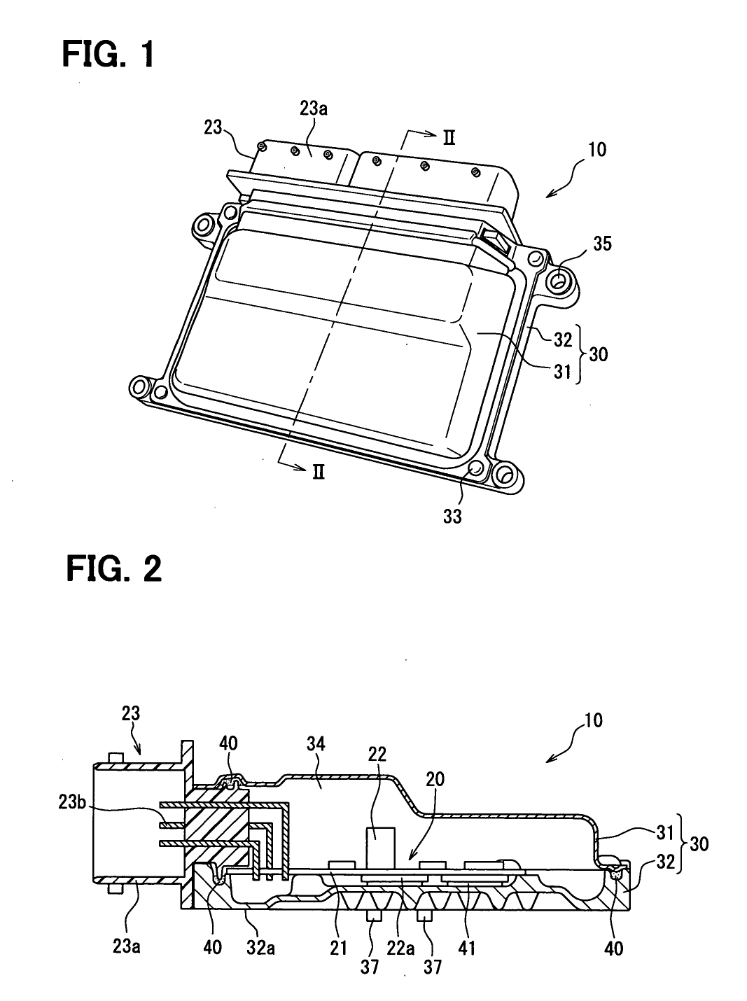

An electronic control unit 10 shown in FIGS. 1 and 2 includes a circuit board 20 having a substrate 21 to which electronic devices 22 are installed, a waterproof housing 30 that houses the circuit board 20, and a sealing member 40. First, a standard structure of the electronic control unit 10 will be described.

The electronic devices 22 such as a microcomputer, a power transistor, a resistor, and a capacitor are installed to the substrate 21, in which wirings including lands as electrodes and via holes for connecting the wirings are formed, thereby providing the circuit board 20 in which a circuit is configured.

In the present embodiment, the electronic devices 22 installed to the substrate 21 include a pressure sensor and a heat-generating element 22a such as a power MOSFET.

Other than the above-described electronic devices 22, a connector 23 that electrically connects the circuit configured in the circuit board 20 to an external device or the like is installed to the substrate 21. In the connector 23, a reference numeral 23a denotes a housing made of electrical insulating material, and a reference numeral 23b denotes a terminal made of electrical conducting material, a part of which is supported by the housing 23a. FIG. 2 shows an example that the terminal 23b of the connector 23 is inserted and installed to the substrate 21. However, an installation structure is not limited to the above example, and a surface mount structure can be applied.

In addition, in FIG. 2, through-holes, into which the terminal 23b is inserted, and the lands are omitted from the substrate 21, and solder that connects the lands to the terminal 23b is also omitted.

The waterproof housing 30 is made of metal material such as aluminum and iron or resin material. The waterproof housing 30 houses the circuit board 20 therein to protect the circuit board 20. The number of components for the waterproof housing 30 is not specifically limited. The waterproof housing 30 may include one component, or may include multiple components.

In the present embodiment, as shown in FIG. 2, the waterproof housing 30 includes a box-shaped case 31, one surface of which is opened, and a shallow cover 32 that closes the opening portion of the case 31. The case 31 and the cover 32 are fixed to each other by a screw 33 so that the waterproof housing 30 having an internal space 34, in which the circuit board 20 is housed, is formed. In the fixing state, a part of the substrate 21 is directly or indirectly sandwiched between the case 31 and the cover 32, and thus, the circuit board 20 is supported at a predetermined position in the waterproof housing 30.

A dividing direction of the waterproof housing 30 including the case 31 and the cover 32 is not specifically limited. In the present embodiment, the waterproof housing 30 is divided into two parts, that is, the case 31 and the cover 32, in the thickness direction.

In the case 31 and the cover 32, a cutting portion (not shown) for the connector, which corresponds to the housing 23a of the connector 23, is formed. The substrate 21 including the electronic devices 22 and a part of the terminal 23b of the connector 23, which is connected to the substrate 21, are housed in the internal space 34 of the waterproof housing 30. The other part of the terminal 23b of the connector 23, which is connected to an external connector, is exposed to the outside of the waterproof housing 30.

Furthermore, the cover 32 has fixing openings 35 at four corners of a peripheral portion thereof. A fixing member for fixing the electronic control unit 10 to a vehicle 50 is inserted into each of the fixing openings 35.

The sealing member 40 air-tightly seals the internal space 34 of the waterproof housing 30 with respect to an engine room 51, which will be described below, and has a function to prevent water from entering into the internal space 34. As shown in FIG. 2, the sealing member 40 is arranged at a position where the case 31 and the cover 32 are opposed to each other in peripheral portions of the case 31 and the cover 32. Moreover, the sealing member 40 is arranged at a position where the housing 23a of the connector 23 and the case 31 are opposed to each other, and at a position where the housing 23a of the connector 23 and the cover 32 are opposed to each other.

In addition, a reference numeral 41 in FIG. 2 is a heat releasing gel, which is arranged to contact the heat-generating element 22a and the cover 32 and transfers heat of the heat-generating element 22a to the cover 32.

Next, characterizing portions of the fixation structure, in which the electronic control unit 10 is fixed to a fixation member of the vehicle 50, will be described. In addition, the configuration of the above-described electronic control unit 10 is simplified in FIG. 4. For, example, the cover 32 configuring the waterproof housing 30 is illustrated in a planar shape.

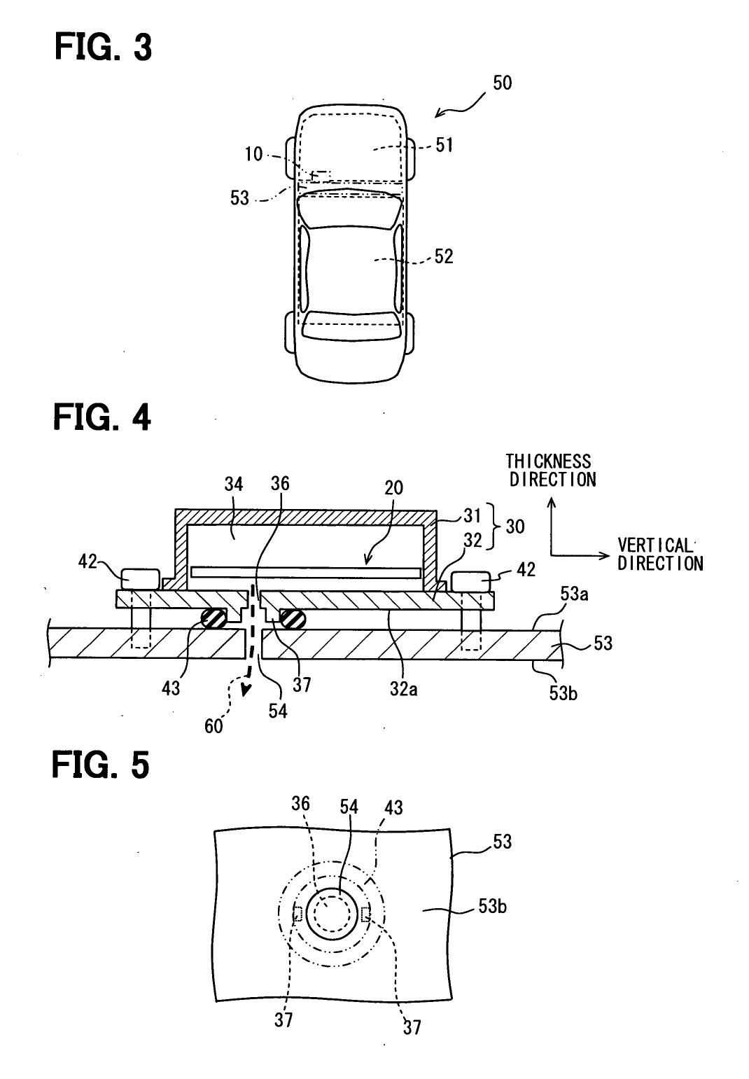

As shown in FIG. 3, the electronic control unit 10 is placed in the engine room 51 of the vehicle 50, and is fixed to the partition wall 53 that partitions the vehicle 50 into the engine room 51 and a passenger compartment 52. The partition wall 53 corresponds to the fixation member of the vehicle 50.

The following points 1) to 4) are the characterizing portions. 1) The electronic control unit 10 is fixed to the partition wall 53 by a fixing member. 2) An opening 36 is formed in a part of a portion of the waterproof housing 30 configuring the electronic control unit 10, which is opposed to the partition wall 53. 3) A through-hole 54 is formed in a part of a portion of the partition wall 53, which is opposed to the electronic control unit 10. 4) An annular rubber member 43 is arranged between the electronic control unit 10 and the partition wall 53 so as to surround the opening 36 and the through-hole 54, and the rubber member 43 is clamped between the electronic control unit 10 and the partition wall 53.

The electronic control unit 10 is fixed to the partition wall 53 by the fixing member. In the present embodiment, a screw 42 that is inserted in the fixing opening 35 of the cover 32 configuring the waterproof housing 30 is screwed into a groove (not shown), which is formed to have a predetermined depth from a surface 53a of the partition wall 53 at a side of the engine room 51, so that the electronic control unit 10 is fixed to the partition wall 53. In addition, a reference numeral 53b in FIG. 4 is a rear surface of the surface 53a, that is, a surface of the partition wall 53 at a side of the passenger compartment 52.

As shown in FIG. 4, the opening 36 is formed in the part of the portion of the waterproof housing 30 configuring the electronic control unit 10, which is opposed to the partition wall 53. The opening 36 is an air hole for ventilating the internal space 34 of the waterproof housing 30 and the inside of the passenger compartment 52. A cross-sectional shape (opening shape) of the opening 36 is not specifically limited.

In the present embodiment, one opening 36 having a circular cross-section with a fixed diameter is formed in the cover 32 configuring the waterproof housing 30. In the state where the electronic control unit 10 is fixed to the partition wall 53, a penetrating direction of the opening 36 substantially corresponds to the thickness direction of the partition wall 53. The diameter of the opening 36 is 0.1 mm or more, and is set to have a dimension (e.g., a few millimeters) such that foreign substances cannot enter into the internal space 34 through the opening 36. By setting the diameter of the opening 36 to be 0.1 mm or more, a ventilation rate which is substantially the same as that of the commonly-known breathing filter (16 cm³/kPa·min to 36 cm³/kPa·min) can be obtained.

The opening 36 can be formed when the waterproof housing 30 is fabricated by casting such as press molding and aluminum die-casting, and injection molding of resin. Alternatively, the opening 36 can be formed by a post-processing step by the use of a drill or a laser after the waterproof housing 30 is fabricated.

Furthermore, the waterproof housing 30 has a rib 37 having, a predetermined height in the thickness direction. The rib 37 is formed at one portion of the waterproof housing 30, which is opposed to the partition wall 53 and is different from the portion in which the opening 36 is formed. The rib 37 has a function as a stopper that prevents compressibility of the rubber member 43, which is clamped between the electronic control unit 10 and the partition wall 53, from exceeding a predetermined value when the electronic control unit 10 is fixed to the partition wall 53 by the fixing member (screw 42).

In the present embodiment, the height of the rib 37 is set such that the compressibility of the rubber member 43 does not exceed 30%. For this reason, the rubber member 43 can be compressed by being fastened with the screw 42 until the compressibility of the rubber member 43 becomes 30%. However, when the compressibility of the rubber member 43 becomes about 30%, an end portion of the rib 37 contacts the opposed surface 53a of the partition wall 53. Thus, even if the screw 42 is fastened, a distance between an opposed surface 32a of the cover 32 and the surface 53a of the partition wall 53 is not reduced any more.

The rib 37 may be integrally formed as one part of the cover 32, or may be fixed to the cover 32. Although arrangement of the rib 37 is not specifically limited, it is preferable that the rib 37 is arranged near the rubber member 43.

In the present embodiment, the rib 37 is integrally formed with the cover 32 as one part of the cover 32. Moreover, as shown in FIGS. 4 and 5, a pair of ribs 37 is formed at positions, which are opposed to each other with the opening 36 and the through-hole 54 interposed therebetween, such that the ribs 37 are located adjacent to an inner periphery of the annular rubber member 43. Since the ribs 37 are located adjacent to the inner periphery of the rubber member 43, the rubber member 43 can be temporary held by the ribs 37 when the electronic control unit 10 is fixed to the partition wall 53. Thus, it becomes easy to secure a positional relation among the rubber member 43, the opening 36, and the through-hole 54.

The rib 37 may be formed at a side of an outer periphery of the rubber member 43, or may be formed at a position far away from the rubber member 43 (at a position where the rib 37 does not contact the rubber member 43). Moreover, multiple ribs 37, for example, three ribs 37, may be used. Furthermore, the annular rib 37 that surrounds the opening 36 and the through-hole 54 may be used.

In contrast, the through-hole 54 is formed along the thickness direction and in a part of a portion of the partition wall 53, which is opposed to the electronic control unit 10. The through-hole 54 is an air hole, which is formed in the partition wall 53, for ventilating the internal space 34 of the waterproof housing 30 and the inside of the passenger compartment 52. A cross-sectional shape (opening shape) of the through-hole 54 is not specifically limited. A positional relation between the through-hole 54 and the above-described opening 36 at a side of the electronic control unit 10, and a size of each of the through-hole 54 and the opening 36 are not specifically limited.

In the present embodiment, one through-hole 54 having a circular cross-section with a fixed diameter is formed. A diameter of the through-hole 54 is larger than that of the opening 36, and central axes of the through-hole 54 and the opening 36 correspond to each other. As shown in FIG. 5, the through-hole 54 is located to overlap with the opening 36 in the vertical direction, and the opening 36 and the through-hole 54 are arranged in a concentric pattern.

The annular rubber member 43 is arranged in an opposing portion, in which the cover 32 of the electronic control unit 10 and the partition wall 53 are opposed to each other, so as to surround the through-hole 54 formed in the partition wall 53 and the opening 36 formed in the cover 32 in the vertical direction. The rubber member 43 is clamped between the opposed surface 32a of the cover 32 and the surface 53a of the partition wall 53. The rubber member 43 clamped between the opposed surface 32a and the surface 53a is in an elastic deformation state, and the rubber member 43 air-tightly contacts the opposed surface 32a of the cover 32 and the surface 53a of the partition wall 53.

The annular shape of the rubber member 43 is not specifically limited. In the present embodiment, as shown in FIG. 5, the annular rubber member 43 (so-called O-ring) is used. The annular rubber member 43, the opening 36, and the through-hole 54 are arranged in a concentric pattern in the state where the rubber member 43 is positioned by the rib 37 and is clamped between the opposed surface 32a and the surface 53a.

In the present embodiment, a fastened degree by the screw 42 is controlled such that the rubber member 43 air-tightly contacts the opposed surface 32a of the cover 32 and the surface 53a of the partition wall 53, in other words, the compressibility of the rubber member 43 becomes 10% or more and 30% or less, due to the elastic deformation. As described above, since the rib 37 is formed on the opposed surface 32a of the cover 32, the rubber member 43 is not deformed when the compressibility thereof exceeds 30%. In particular, the rubber member 43 has a thickness of 3 mm in the penetrating direction when the rubber, member 43 is not deformed. When the rubber member 43 is clamped between the opposed surface 32a and the surface 53a, the rubber member 43 is dented by 0.3 mm to 0.9 mm. If the distance between the opposed surface 32a of the cover 32 and the surface 53a of the partition wall 53 is constant, the rib 37 having a height of 2.1 mm from the opposed surface 32a as a standard is formed.

As described above, according to the fixation structure of the electronic control unit 10 of the present embodiment, the annular rubber member 43 is arranged in the opposing portion, in which the electronic control unit 10 and the partition wall 53 are opposed to each other, so as to surround the through-hole 54 formed in the partition wall 53 and the opening 36 formed in the electronic control unit 10, in the vertical direction. The rubber member 43 is sandwiched between the electronic control unit 10, which is fixed to the partition wall 53 with the screw 42, and the partition wall 53. The rubber member 43 sandwiched between the electronic control unit 10 and the partition wall 53 is elastically deformed so that the rubber member 43 air-tightly contacts the electronic control unit 10 and the partition wall 53.

In this manner, the inner periphery side of the rubber member 43 becomes an airtight space (waterproof space). Furthermore, the internal space 34 of the waterproof housing 30 in the electronic control unit 10 is communicated with the passenger compartment 52 through the opening 36 of the cover 32, the annular rubber member 43 and the through-hole 54 of the partition wall 53.

Thus, for example, even if a pressure in the internal space 34 is increased, expanded air in the internal space 34 can be made to flow to a side of the passenger compartment 52 by an airflow 60 indicated by the dashed arrow in FIG. 4. That is, a pressure difference between the pressure in the internal space 34 and a pressure outside the internal space 34 (internal-external pressure difference) can be suppressed without using a breathing filter, and thus, deformation of the waterproof housing 30 can be suppressed. Furthermore, since the pressure in the internal space 34 becomes substantially equal to a pressure in the passenger compartment 52 (external pressure), the pressure sensor as the electronic device 22 can operate normally.

Specifically, in the present embodiment, since the opening 36 of the electronic control unit 10 is located to overlap with the through-hole 54 of the partition wall 53 in the vertical direction, it becomes easy to generate the airflow 60.

According to the above-described configuration, even if the electronic control unit 10 including the heat-generating element 22a is placed in the engine room 51 which becomes a high-temperature environment, heated air in the internal space 34 is transferred to the side of the passenger compartment 52, and a temperature of the internal space 34 can be lowered. Therefore, an environment with a temperature equal to or lower than an operation security temperature (e.g., 120° C.) of the electronic devices 22 such as the heat-generating element 22a can be secured.

Furthermore, the internal space 34 of the electronic control unit 10 is communicated with only the side of the passenger compartment 52, and is air-tightly blocked with respect to the engine room 51. Thus, although the electronic control unit 10 is arranged at the side of the engine room 51, a waterproof property of the internal space 34 can be secured.

Specifically, in the present invention, by using the configuration in which the electronic control unit 10 is fastened and fixed to the partition wall 53 with the annular rubber member 43, the waterproof property can be secured without using a breathing filter, and the internal-external pressure difference can be suppressed. Therefore, the configuration is simplified compared with the configuration of the related arts, and thereby, the manufacturing cost can also be reduced.

Furthermore, since the electronic control unit 10 is fixed to the partition wall 53, heat generated in the heat-generating element 22a can be released to the partition wall 53 through the heat releasing gel 41; the cover 32, and the screw 42. In the case where the rib 37 contacts the partition wall 53 by fastening with the screw 42, heat can be released to the partition wall 53 from the cover 32. Therefore, a heat-releasing property can be improved.

### Second Embodiment

Next, the second embodiment of the present invention will be described. Since the fixation structure of the electronic control unit of the second embodiment has many features which are common to those described in the first embodiment, hereinafter, detailed description about the common features will not be repeated and different features will be mainly described. In addition, the same reference numeral is designated with respect to a portion corresponding to the portion in the first embodiment.

The common feature in the present embodiment is that multiple openings are formed in the electronic control unit 10 as the opening 36 or multiple through-holes are formed in the partition wall 53 as the though-hole 54.

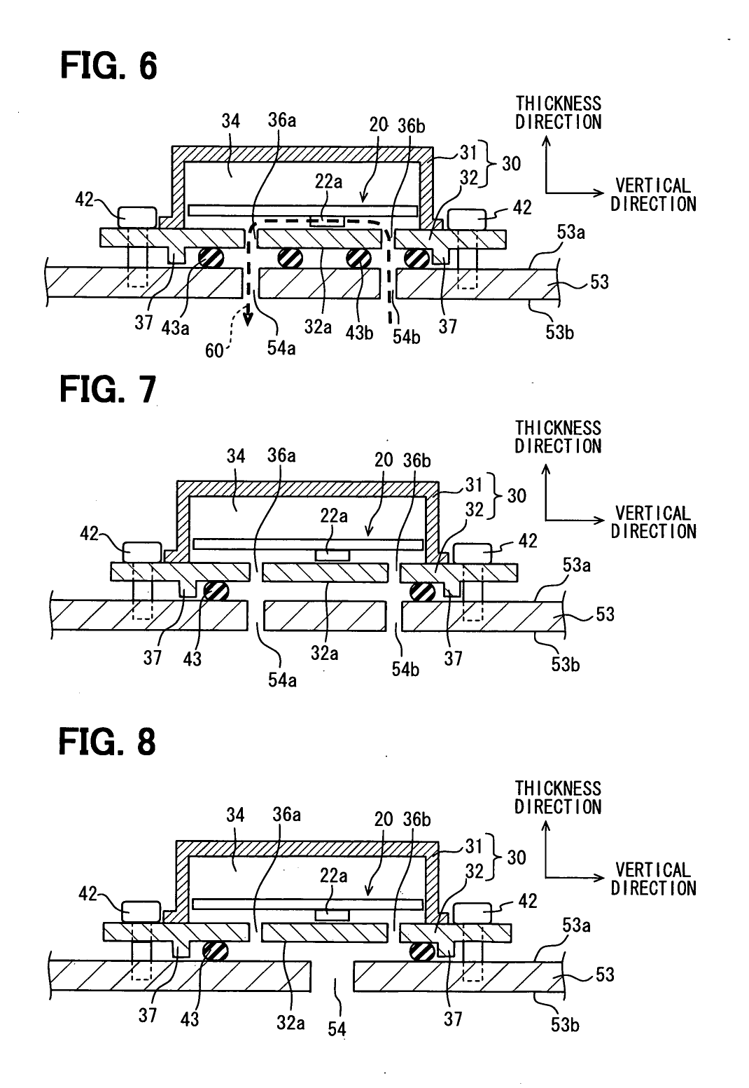

According to the example shown in FIG. 6, two openings 36a, 36b as the opening 36 are formed in the cover 32 of the waterproof housing 30, and two through-holes 54a, 54b as the through-hole 54 are formed to correspond to the openings 36a, 36b, respectively. The opening 36a is located to overlap with the through-hole 54a in the vertical direction, and the opening 36b is located to overlap with the through-hole 54b in the vertical direction.

Furthermore, the openings 36a, 36b and the through-holes 54a, 54b are formed such that the heat-generating element 22a is located over an imaginary straight line stretching between the two openings 36a, 36b.

As the rubber member 43, two rubber members 43a, 43b are arranged. The rubber member 43a surrounds the opening 36a and the through-hole 54a, and the rubber member 43b surrounds the opening 36b and the through-hole 54b.

Furthermore, the ribs 37 protruding from the opposed surface 32a of the cover 32 are formed so as to sandwich the two openings 36a, 36b (and the two rubber members 43a, 43b) over the imaginary straight line stretching between the two openings 36a, 36b.

Also in such a configuration, for example, if the pressure in the internal space 34 is increased, the expanded air in the internal space 34 can be made to flow to the side of the passenger compartment 52.

Furthermore, when a temperature difference (a bias in temperature distribution) is generated in the internal space 34 of the electronic control unit 10 due to the heat generated in the heat-generating element 22a, the airflow 60, which enters into the internal space 34 from the passenger compartment 52 and returns to the passenger compartment 52, is generated as indicated by the dashed arrow in FIG. 6. That is, air at the side of the passenger compartment 52, a temperature of which is lower than that in the engine room 51, is drawn into the internal space 34 of the electronic control unit 10, and the air can be circulated in the internal space 34. Therefore, an environment with a temperature equal to or lower than the operation security temperature (e.g., 120° C.) of the electronic devices 22 such as the heat-generating element 22a can be secured.

In this manner, since the temperature of the internal space 34 (temperature of the electronic devices 22) can be lowered, the electronic device 22 (circuit board 20) with a low heatproof temperature can be used; and thus, the manufacturing cost can be reduced.

Specifically, the number of the openings 36a, 36b (opening 36) of the electronic control unit 10 is the same as that of the through-holes 54a, 54b (through-hole 54) of the partition wall 53, and each of the openings 36a, 36b are located to overlap with a corresponding one of the through-holes 54a, 54b. Therefore, it becomes easy to generate the airflow 60.

In addition, the rubber member 43a is arranged to surround the opening 36a and the through-hole 54a, which overlap with each other, and the rubber member 43b is arranged to surround the opening 36b and the through-hole 54b, which overlap with each other. Since a flow passage configured by the opening 36a and the through-hole 54a and the rubber member 43a, and a flow passage configured by the opening 36b and the through-hole 54b and the rubber member 43b are separately formed, an air-circulating effect can be improved.

Furthermore, the heat-generating element 22a is located over the imaginary straight line stretching between the two openings 36a, 36b. Therefore, the airflow 60 passes over the heat-generating element 22a, and thereby, the heat-generating element 22a can be effectively cooled.

In FIG. 6, the ribs 37, are arranged at positions where the ribs 37 do not contact the respective rubber members 43a, 43b. However, the ribs 37 may be arranged at positions where the ribs 37 contact the respective rubber members 43a, 43b. For example, the ribs 37 may be arranged to contact an inner periphery of the rubber member 43a and an inner periphery of the rubber member 43b, respectively (refer to FIG. 4).

In FIG. 6, the rubber member 43a is arranged to surround the opening 36a and the through-hole 54a, which overlap with each other, and the rubber member 43b is arranged to surround the opening 36b and the through-hole 54b, which overlap with each other. However, as shown in FIG. 7, one rubber member 43 may be arranged to surround all the openings 36a, 36b and the through-holes 54a, 54b in the vertical direction. Thus, the number of the rubber members 43 can be reduced.

Furthermore, in FIG. 6, the two openings 36a, 36b as the multiple openings 36 are formed, and the two through-holes 54a, 54b as the multiple through-holes 54 are formed. However, the number of the openings 36 and the number of the through-holes 54 are not limited to two. The number of the openings 36 may not be the same as the number of the through-holes 54. The number of the openings 36 and the number of the through-holes 54 are not limited, as long as multiple openings as the opening 36 or multiple through-holes as the through-hole 54 are formed.

For example, in FIG. 8, the two openings 36a, 36b are formed in the cover 32 of the electronic control unit 10 as well as FIG. 6, and the one through-hole 54 is formed in the partition wall 53 as well as FIG. 4. The one rubber member 43 is arranged between the opposed surface 32a of the cover 32 and the surface 53a of the partition wall 53 so as to surround the two openings 36a, 36b and the one through-hole 54 in the vertical direction.

Furthermore, the through-hole 54 is formed between the openings 36a, 36b in an extending direction of an imaginary straight line stretching between the two openings 36a, 36b. In FIG. 8, the diameter of the through-hole 54 is larger than that of each of the openings 36a, 36b.

Also in such a configuration, for example, if the pressure in the internal space 34 is increased, the expanded air in the internal space 34 can be made to flow to the side of the passenger compartment 52. Furthermore, since the multiple openings 36a, 36b are formed in the cover 32, when the temperature difference (the bias in the temperature distribution) is generated in the internal space 34 of the electronic control unit 10 due to the heat generated in the heat-generating element 22a, an airflow such as the airflow 60 shown in FIG. 6 is generated between the internal space 34 and at least a space surrounded by the rubber member 43. Since the space surrounded by the rubber member 43 is communicated with the passenger compartment 52 through the through-hole 54, if the pressure difference (the temperature difference) is generated, the airflow is generated. Therefore, an effect similar to the effect obtained by the configuration shown in FIG. 6 can be obtained.

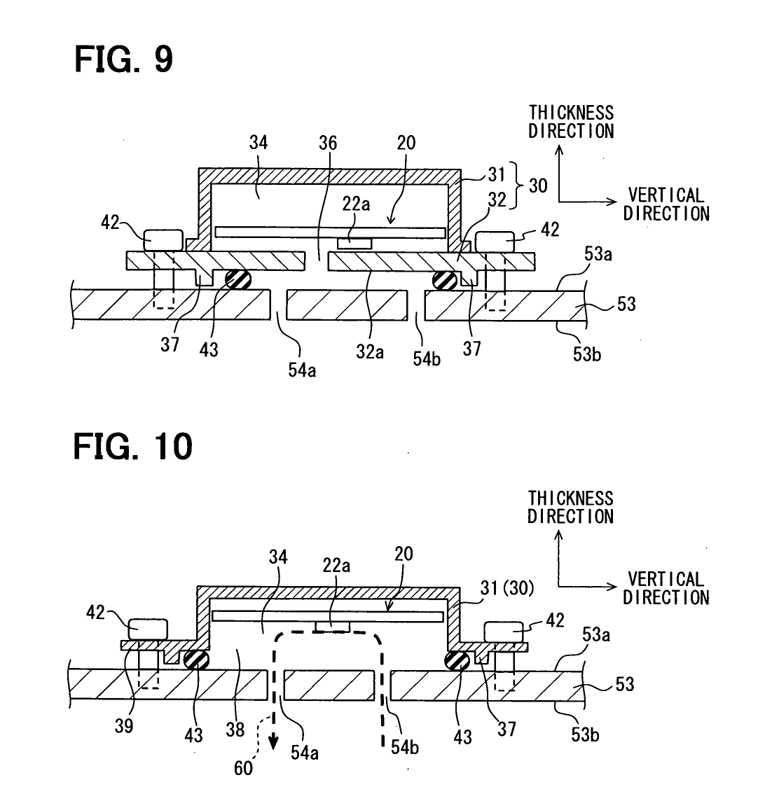

In contrast, in FIG. 9, the one opening 36 is formed in the cover 32 of the electronic control unit 10 as well as FIG. 4, and the two through-holes 54a, 54b are formed in the partition wall 53 as well as FIG. 6. The one rubber member 43 is arranged between the opposed surface 32a of the cover 32 and the surface 53a of the partition wall 53 so as to surround the one opening 36 and the two through-holes 54a, 54b in the vertical direction.

The opening 36 is located near the through-hole 54a of the two through-holes 54a, 54b in the vertical direction. That is, the opening 36 is located nearer the through-hole 54a in relation to the through-hole 54b in the vertical direction. In FIG. 9, the diameter of the opening 36 is larger than that of each of the through-holes 54a, 54b.

Also in such a configuration, for example, if the pressure in the internal space 34 is increased, the expanded air in the internal space 34 can be made to flow to the side of the passenger compartment 52. Since the multiple through-holes 54a, 54b are formed in the partition wall 53 and the opening 36 is formed nearer the one through-hole 54a than the other through-hole 54b, a temperature at a side of the through-hole 54a becomes higher than that at a side of the through-hole 54b. Thus, because of the temperature difference, an airflow such as the airflow 60 shown in FIG. 6 is generated between the space surrounded by the rubber member 43 and the passenger compartment 52 through the through-holes 54a, 54b. Therefore, an effect similar to the effect obtained by the configuration shown in FIG. 6 can be obtained.

### Third Embodiment

Next, a third embodiment of the present invention will be described. Since the fixation structure of the electronic control unit of the third embodiment has many features which are common to those shown in the first and second embodiments, hereinafter, detailed description about the common features will not be repeated and different features will be mainly described. In addition, the same reference numeral is designated with respect to a portion corresponding to the portion in the first and second embodiments.

The feature in the present embodiment is that the electronic control unit 10 has only a component corresponding to the case 31 of the above-described embodiments as the waterproof housing 30, and the partition wall 53 is used as a part of a waterproof housing in the state where the electronic control unit 10 is fixed to the partition wall 53.

The configuration shown in FIG. 10 does not include the cover 32 compared with the configuration shown in FIGS. 1 and 2. An outer peripheral portion 39 which surrounds an opening 38 is configured by the case 31, a part of the housing 23a of the connector 23, and an end portion of the sealing member 40. In FIG. 10, only the case 31 is shown for the sake of convenience. The rib 37 is formed at a part of a portion of the case 31, which configures the outer peripheral portion 39.

Although not shown, in such a configuration, the circuit board 20 is fixed to the case 31 by being fastened with a screw, for example.

The two through-holes 54a, 54b as the through-hole 54 are formed in the partition wall 53. The annular rubber member 43 is arranged between the outer peripheral portion 39 and a portion of the surface 53a of the partition wall 53, which is opposed to the outer peripheral portion 39, so as to surround the two through-holes 54a, 54b and the opening 38. The rubber member 43 is clamped between the outer peripheral portion 39 and the surface 53a of the partition wall 53 by being fastened with the screw 42.

That is, a space, which is air-tightly blocked with respect to the engine room 51 and is communicated with the passenger compartment 52, is formed by the electronic control unit 10, the rubber member 43, and the partition wall 53. The space includes the internal space 34 of the electronic control unit 10.

Also in such a configuration, for example, if the pressure in the internal space 34 is increased, the expanded air in the internal space 34 can be made to flow to the side of the passenger compartment 52. Furthermore, since the multiple through-holes 54a, 54b are formed in the partition wall 53, when the temperature difference (the bias in the temperature distribution) is generated in the internal space 34 of the electronic control unit 10 due to the heat generated in the heat-generating element 22a, the airflow 60 shown in FIG. 10 is generated between the internal space 34 and the passenger compartment 52 through the through-holes 54a, 54b. That is, air at the side of the passenger compartment 52, a temperature of which is lower than that in the engine room 51, is drawn into the internal space 34 of the electronic control unit 10, and the air can be circulated in the internal space 34. Therefore, an environment with a temperature equal to or lower than the operation security temperature (e.g., 120° C.) of the electronic devices 22 such as the heat-generating element 22a can be secured.

In this manner, since the temperature of the internal space 34 (temperature of the electronic device 22) can be lowered, the electronic device 22 (circuit board 20) with a low heatproof temperature can be used, and thus, the manufacturing cost can be reduced.

In the above-described embodiments, the opening 36 is daringly formed in the waterproof housing 30 having the internal space 34, which becomes an airtight space if the opening 36 is not formed, and thus, the internal space 34 is communicated with the passenger compartment 52. In contrast, in the present embodiment, it is not necessary to form the opening 36 in the waterproof housing 30. That is, since the partition wall 53 can be used as a part of the waterproof housing 30, only one component is sufficient for the waterproof housing 30. Therefore, the manufacturing cost can also be reduced.

Furthermore, since the partition wall 53 having large heat capacity is used as a part of the waterproof housing 30, the heat-releasing property can also be improved.

In FIG. 10, the two through-holes 54a, 54b as the through-hole 54 are formed in the partition wall 53. However, the number of the through-holes 54 is not specifically limited.

In the present embodiment, the outer peripheral portion 39 which surrounds the opening 38 is configured by the case 31, the part of the housing 23a of the connector 23, and the end portion of the sealing member 40 interposed between the case 31 and the housing 23a. However, the outer peripheral portion 39 which surrounds the opening 38 may be configured by only the case 31.

Hereinbefore, the preferred embodiments of the present invention are described. However, the present invention is not limited to the above-described embodiments, and various changes can be made without departing from the scope of the invention.

In the above-described embodiments, the electronic control unit 10 having the waterproof structure, which is used as the engine ECU for the vehicle, is shown as the in-vehicle waterproof device. Moreover, the circuit board 20 is shown as the electronic device housed in the waterproof housing. However, the electronic device is not limited to the circuit board 20, and the use of the in-vehicle waterproof device is not limited to the above-described example.

In the above-described embodiments, the cross-sectional shape of each of the opening 36 and the through-hole 54 is the circular shape. However, the cross-sectional Shape is not limited to the circular shape. The cross-sectional shape may be a polygonal shape such as a rectangular shape. In addition, the shape of the rubber member 43 is not limited to the annular shape.

In the above-described embodiments, the rib 37 as the stopper is formed on the waterproof housing 30 of the electronic control unit 10. However, instead of the rib 37, a stopper protruding from the surface 53a of the partition wall 53 may be used.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. An electronic apparatus for a vehicle which includes a partition wall that partitions between an engine room and a passenger compartment of the vehicle, the electronic apparatus comprising:
at least one electronic device;
a housing that receives the at least one electronic device in an interior of the housing, wherein:
the housing is adapted to be placed in the engine room of the vehicle and is adapted to be fixed to a mount area of the partition wall of the vehicle, which has a through-hole, with at least one fixing member;
the through-hole extends through the partition wall at the mount area to oppose the housing upon fixation of the housing to the mount area of the partition wall with the at least one fixing member; and
the housing includes an opening, which communicates between the interior of the housing and the passenger compartment through the through-hole of the partition wall; and
an annular rubber member that surrounds the opening of the housing and is adapted to be placed in an imaginary plane that is generally perpendicular to a penetrating direction of the through-hole of the partition wall to surround the through-hole of the partition wall and the opening of the housing, wherein the rubber member is adapted to be clamped between the housing and the partition wall upon the fixation of the housing to the partition wall with the at least one fixing member.

2. The electronic apparatus according to claim 1, wherein:
the opening of the housing is a first opening;
the housing further includes a second opening; and
the first and second openings of the housing are surrounded by the rubber member in a direction generally parallel to the imaginary plane.

3. The electronic apparatus according to claim 1, wherein:
the through-hole of the partition wall is a first through-hole;
the partition wall further includes a second through-hole; and
the first and second through-holes of the partition wall are surrounded by the rubber member in a direction generally parallel to the imaginary plane.

4. The electronic apparatus according to claim 1, wherein:
the opening of the housing is one of a plurality of openings formed in the housing;
the through-hole of the partition wall is one of a plurality of through-holes formed in the partition wall; and
the number of the plurality of openings is the same as the number of the plurality of through-holes.

5. The electronic apparatus according to claim 4, wherein
each of the plurality of openings and a corresponding one of the plurality of through-holes are placed one after another in a direction generally parallel to the imaginary plane.

6. The electronic apparatus according to claim 5, wherein:
the rubber member is one of a plurality of rubber members;
the number of the plurality of rubber members is the same as the number of the plurality of openings and the number of the plurality of through-holes; and
each of the plurality of rubber members surrounds a corresponding one of the plurality of openings and a corresponding one of the plurality of through-holes in the direction generally parallel to the imaginary plane.

7. The electronic apparatus according to claim 1, wherein:
the housing has an outer peripheral portion that surrounds the opening;
the rubber member is arranged between the outer peripheral portion and the partition wall; and
the at least one electronic device is arranged in a space defined by the housing, the rubber member, and the partition wall.

8. The electronic apparatus according to claim 7, wherein:
the through-hole of the partition wall is a first through-hole;
the partition wall further includes a second through-hole; and
the first and second through-holes of the partition wall are surrounded by the rubber member in a direction generally parallel to the imaginary plane.

9. The electronic apparatus according to claim 1, wherein:
at least one of the housing and the partition wall has a stopper having a predetermined height in a direction generally perpendicular to the imaginary plane; and
the stopper is located in an opposing area in which the housing and the partition wall are opposed to each other in a direction generally perpendicular to the imaginary plane.

10. The electronic apparatus according to claim 1, wherein
the electronic device is a pressure sensor.
